(19) United States
(12) Patent Application Publication
(10) Pub. No.: US 2026/0304859 A1
(43) Pub. Date: Oct. 1, 2026

(54) FORMING A SUPERJUNCTION DEVICE AND SUPERJUNCTION DEVICE

(71) Applicant: Infineon Technologies Austria AG, Villach (AT)

(72) Inventor: Armin Willmeroth, Friedberg (DE)

(21) Appl. No.: 19/573,171

(22) Filed: Mar. 20, 2026

(30) Foreign Application Priority Data
Mar. 28, 2025 (DE) 102025112317.9

(51) Int. Cl. H10D 62/10; H10D 30/66; H10D 62/00

(52) U.S. Cl. CPC H10D 62/111; H10D 30/668; H10D 62/054

(57) ABSTRACT

A method for forming a superjunction device and a superjunction device are disclosed. The superjunction device includes: a first superjunction region in an inner region of a semiconductor body, the first superjunction region including a plurality of first regions of a first doping type and a plurality of second regions of a second doping type complementary to the first doping type; a second superjunction region in an edge region of the semiconductor body, the second superjunction region including a plurality of third regions of the first doping type and a plurality of fourth regions of the second doping type; and a first termination region of the first doping type and a second termination region of the second doping type in the edge region. The first termination region is arranged between the second termination region and edge surfaces of the semiconductor body in lateral directions.

### TECHNICAL FIELD

This disclosure relates in general to a method for forming a superjunction device, in particular a vertical superjunction transistor device.

### BACKGROUND

A vertical transistor device is a transistor device in which source regions of transistor cells are spaced apart from a drain region of the transistor device in a vertical direction of a semiconductor body. The source regions are coupled to a source node, and the drain region is coupled to a drain node. The source regions may be located close to a first surface of the semiconductor body, and the drain region may be located close to a second surface opposite the first surface. Side surfaces (sidewalls) of the semiconductor body terminate the semiconductor body in lateral directions perpendicular to the first and second surfaces.

The transistor cells may be arranged in an inner region of the semiconductor body, wherein the inner region, in lateral directions is surrounded by an edge region. Usually, vertical transistor devices are designed such that the edge region, in sections close to the sidewalls, is connected to the drain region. In this case, an edge termination structure arranged in the edge region absorbs a voltage that may occur between the drain region and the source regions when the transistor device is in an off-state. The voltage blocking capability is the maximum voltage the transistor device can withstand in the off-state. The edge termination structure may be configured to absorb a voltage that is at least equal to or higher than the voltage blocking capability.

A vertical superjunction transistor device further includes a superjunction region with a plurality of first regions of a first doping type coupled to the drain region and a plurality of second regions of a second doping type complementary to the first doping type coupled to the source node.

### SUMMARY

There is a need for an efficient method for forming and edge termination structure in a vertical superjunction device, such as a vertical superjunction transistor device, wherein the edge termination structure is capable of withstanding voltages that may occur between the inner region and the edge region of the superjunction device.

One example relates to a method for forming a superjunction device. The method includes forming a first superjunction region in an inner region of a semiconductor body, the first superjunction region including a plurality of first regions of a first doping type and a plurality of second regions of a second doping type complementary to the first doping type; forming a second superjunction region in an edge region of the semiconductor body, the second superjunction region including a plurality of third regions of the first doping type and a plurality of fourth regions of the second doping type; and forming a first termination region of the first doping type and a second termination region of the second doping type in the edge region. Forming the first superjunction region includes forming a plurality of first semiconductor layers one above the other, forming a second semiconductor layer on top of the first semiconductor layers, and implanting first type dopant atoms and second type dopant atoms into each of the plurality of first semiconductor layers and the second semiconductor layer after forming the respective first or second semiconductor layer and before forming a next one of the first semiconductor layers or the second semiconductor layer. Forming the second superjunction region includes implanting first type dopant atoms and second type dopant atoms into each of the first semiconductor layers. Forming the first termination region includes implanting first type dopant atoms into the second semiconductor layer to form at least one first implanted termination region, and forming the second termination region includes implanting second type dopant atoms into the second semiconductor layer to form at least one first implanted termination region.

Another example relates to a superjunction device. The superjunction device includes: a first superjunction region in an inner region of a semiconductor body, the first superjunction region including a plurality of first regions of a first doping type and a plurality of second regions of a second doping type complementary to the first doping type; a second superjunction region in an edge region of the semiconductor body, the second superjunction region including a plurality of third regions of the first doping type and a plurality of fourth regions of the second doping type; and a first termination region of the first doping type and a second termination region of the second doping type in the edge region. The first termination region is arranged between the second termination region and edge surfaces of the semiconductor body in lateral directions.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 schematically illustrates a vertical cross-sectional view of a superjunction transistor device which includes transistor cells, first and second superjunction regions, and first and second termination regions;

FIG. 2 schematically illustrates a horizontal cross-sectional view of a transistor device of the type illustrated in FIG. 1;

FIGS. 3A-3B illustrate one example of a method for forming the first and second superjunction regions and the first and second termination regions;

FIG. 4 schematically illustrates one example of a method for forming transistor cells;

FIGS. 5A-5B illustrate one example of a method for forming a respective part of the first and second superjunction regions in one semiconductor layer;

FIGS. 6A-6B illustrate one example of a method for forming another part of the first superjunction region and for forming the first and second termination regions in another semiconductor layer;

FIGS. 7-9 illustrate examples of implantation masks that may be used for forming the first and second termination regions in the method according to FIGS. 5A-5B;

FIG. 10 illustrates the magnitude of the field strength of an electric field that may occur in an edge region of a transistor device of the type illustrated in FIG. 1 when the transistor device is in an off-state (blocking state);

FIG. 11 schematically illustrates a vertical cross-sectional view of several transistor cells according to one example;

FIG. 12 schematically illustrates a horizontal cross-sectional view of the transistor cells according to FIG. 11;

FIGS. 13-15 illustrate different examples of and edge termination structure that includes the first and second termination regions;

FIGS. 16-17 illustrate top views of a transistor device according to different examples.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

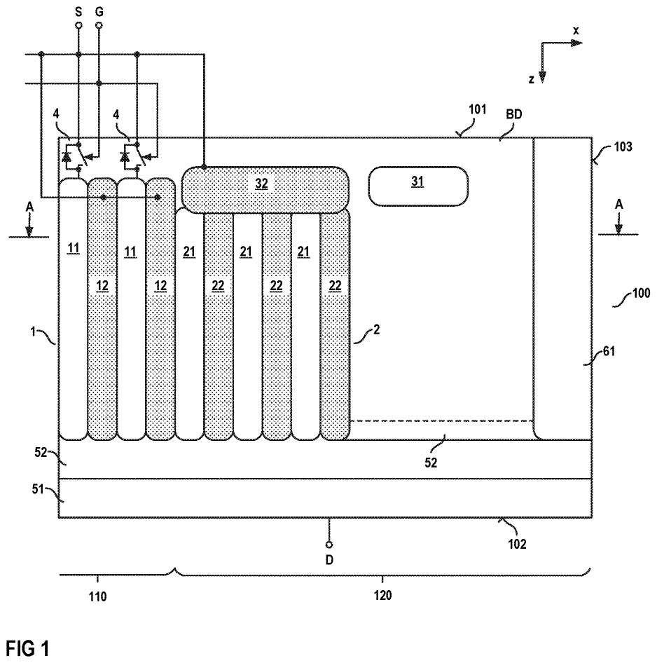

FIG. 1 schematically illustrates a superjunction transistor device according to one example. More specifically, FIG. 1 schematically illustrates a vertical cross-sectional view of a part of the transistor device. The transistor device includes a semiconductor body 100 with a first surface 101 and a second surface 102 opposite the first surface 101. FIG. 1 illustrates a vertical cross-sectional view of the semiconductor body 100 in a vertical section plane which is substantially perpendicular to the first and second surfaces 101, 102.

According to one example, the semiconductor body 100 includes a monocrystalline semiconductor material. The monocrystalline semiconductor material is silicon (Si) or silicon carbide (SiC), for example.

Referring to FIG. 1, the semiconductor body 100 includes an inner region 110 and an edge region 120. The edge region 120 surrounds the inner region 110 in lateral directions, which are directions substantially parallel to the first and second surfaces 101, 102. In the following, “inner region of the transistor device” denotes those regions of the transistor device that include the inner region 110 of the semiconductor body 100, sections of the transistor device located adjacent to the first surface 101 in a vertical direction z, and sections of the transistor device located adjacent to the second surface 102 in the vertical direction z. Furthermore, “edge region of the transistor device” denotes those regions of the transistor device that include the edge region 120 of the semiconductor body 100 and sections of the transistor device located adjacent to the first surface 101 and the second surface 102 in the vertical direction z. The vertical direction z is a direction which is substantially perpendicular to the first and second surfaces 101, 102.

The semiconductor body further includes a first lateral direction x and a second lateral direction y, wherein the second lateral direction y is substantially perpendicular to the first lateral direction x. The first and second lateral directions are substantially parallel to the first and second surfaces 101, 102 and perpendicular to the vertical direction z. With regard to the first lateral direction x it should be noted that, unless stated otherwise, “first lateral direction x” includes both the direction as indicated by the arrow labelled with x in the figures and the opposite direction. The same applies to the second lateral direction y, which includes both the direction as indicated by the arrow labelled with y in the figures and the opposite direction, and the vertical direction z, which includes both the direction as indicated by the arrow labelled with z in the figures and the opposite direction.

Referring to FIG. 1, the superjunction transistor device includes a first superjunction region 1 in the inner region 110 of the semiconductor body 100. The first superjunction region 1 includes first regions 11 of a first doping type and second regions 12 of a second doping type complementary to the first doping type. The first regions 11 and the second regions 12 are arranged alternately in the first lateral direction x of the semiconductor body 100. The first regions 11 of the first superjunction region 1 may also be referred to as a drift regions and the second regions 12 may also be referred to as compensation regions.

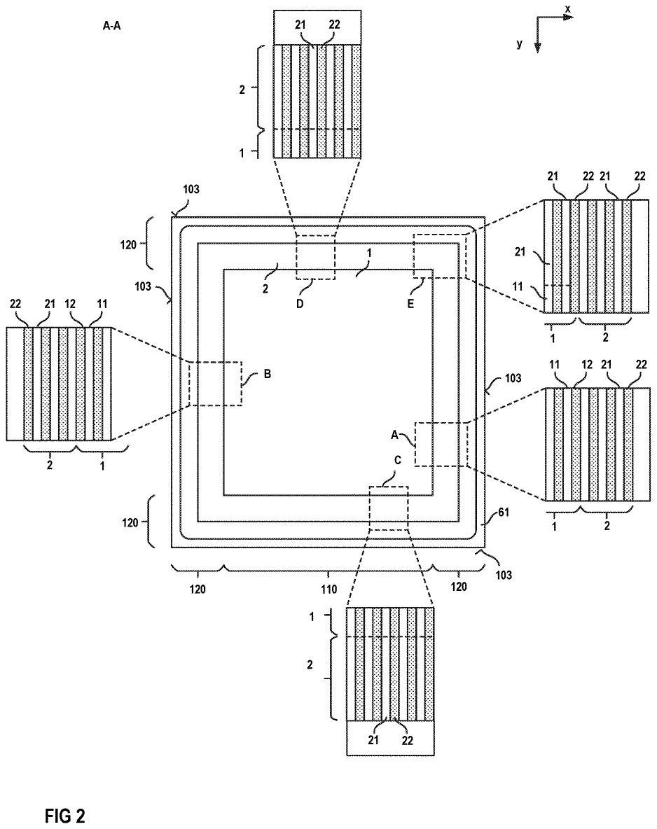

The superjunction transistor device further includes a second superjunction region 2 in the edge region 120 of the semiconductor body 100. The second superjunction region 2 includes third regions 21 of the first doping type and fourth regions 22 of the second doping type. The second superjunction region 2 surrounds the first superjunction region 1 in lateral directions. This is illustrated in FIG. 2.

FIG. 2 schematically illustrates a horizontal cross-sectional view of the transistor device of the type illustrated in FIG. 1 in a horizontal sectional plane A-A intersecting the first and second superjunction regions 1, 2. According to one example, as illustrated in FIG. 2, the first and second regions 11, 12 of the first superjunction region 1 are elongated in the second lateral direction y. Furthermore, the third and fourth regions 21, 22 of the second superjunction region 2 are elongated in the second lateral direction y and arranged alternately in the first lateral direction x.

The second superjunction region 2 surrounding the first superjunction region 1 in lateral directions includes that in the first lateral direction x third and fourth regions 21, 22 are arranged in the edge region 120 between the first superjunction region 1 and each of the respective opposite two edge surfaces 103. More specifically, in the direction perpendicular to the longitudinal directions of the first and second regions 11, 12 the second superjunction region 2 includes elongated third and fourth regions 23, 24 that are essentially parallel to the elongated first and second regions 11, 12 and are arranged alternately in the first lateral direction x. This is illustrated in details A and B in FIG. 2.

Furthermore, the second superjunction region 2 surrounding the first superjunction region 1 in lateral directions further includes that in the second lateral direction y third regions 21 adjoin lateral ends of the first regions 11 and are arranged between the first regions 11 and respective opposite edge surfaces 103, and fourth regions 24 adjoin lateral ends of the second regions 12 and are arranged between the second regions 12 and respective opposite edge surfaces 103. This is illustrated in details C and D in FIG. 2.

Detail E according to FIG. 2 illustrates portions of the first and second superjunction regions 1, 2 in a corner of the first and second superjunction regions 1, 2.

As illustrated in FIG. 2, the second superjunction region 2 may be spaced apart from the edge surfaces 103 in the lateral directions.

The second superjunction region 2 with the third regions 21 and the fourth regions 22 is part of an edge termination structure of the transistor device. Referring to FIG. 1, the edge termination structure further includes a first termination region 31 of the first doping type and a second termination region 32 of the second doping type. The second termination region 32 is arranged closer to the inner region 110 than the first termination region 31. That is, the second termination region 32 is arranged between the first termination region 31 and the inner region 100, and the first termination region 31 is arranged between the second termination region 32 and the edge surface 103.

The edge termination structure may further include a field stop region 61 of the first doping type arranged between the second superjunction region 2 and the edge surfaces 103. According to one example, the field stop region 61 is spaced apart from the second superjunction region 2. According to one example, the field stop region 61 adjoins the edge surfaces 103. According to one example, the field stop region 61 is a contiguous doped region that laterally surrounds the first and second superjunction regions 1, 2.

Referring to FIG. 1, the transistor device further includes a drain region 51 of the first doping type. The drain region 51 is arranged between the first and second superjunction regions 1, 2 and the second surface 102 and may adjoin the second surface 102. The drain region 51 forms a drain node D or is connected to a drain node D of the transistor device.

According to one example, as illustrated in FIG. 1, the drain region 51 is spaced apart from the first and second superjunction regions 1, 2 in the vertical direction z. In this example, a buffer region 52 of the first doping type is arranged between the drain region 51 and the first and second superjunction regions 1, 2. A doping concentration of the buffer region 52 is lower than a doping concentration of the drain region 51, such as more than 2 orders of magnitude lower than the doping concentration of the drain region 51.

The doping concentration of the drain region 51 is in a range of between 5E18 cm⁻³ and 5E20 cm⁻³ and the doping concentration of the buffer region 52 is in a range of between 5E15 cm⁻³ and 5E16 cm⁻³, for example. Doping concentrations of the first, second, third and fourth regions 11, 12, 21, 22 are in a range of between 3E15 cm⁻³ and 3E16 cm⁻³, for example. The doping concentration of the field stop region 61 is in the same range as the doping concentration of the first, second, third and fourth regions 11, 12, 21, 22 or may be slightly higher. (The lateral dimensions of the field stop region 61 are larger than the lateral dimensions of the first, second, third and fourth regions 11, 12, 21, 22. Thus, different from the first, second, third, and fourth regions 11, 12, 21, 22, lateral diffusion does not significantly reduce the doping concentration of the field stop region 61).

The drain region 51 and the buffer region 52 are arranged in the inner region 110 and the edge region 120 of the semiconductor body 100. The buffer region 52 electrically couples the first regions 11 of the first superjunction region 1 and the third regions 21 of the second superjunction region 2, which are of the same (the first) doping type as the buffer region 52, to the drain region 51. Furthermore, the buffer region 52 may adjoin the field stop region 61 and electrically couple the field stop region 61 to the drain region 51.

Referring to FIG. 1, the transistor device further includes transistor cells 4 that are at least partially integrated in the inner region 110 of the semiconductor body 100. This includes that at least active device regions, such as source and body regions (explained herein further below) are integrated in the inner region 110 of the semiconductor body 100. Each transistor cell 4 is coupled between a source node S of the transistor device and at least one of the first regions 11 of the first superjunction region 1. Furthermore, each transistor cell 4 is configured to control a conducting channel between the source node S and the respective first region 11. The transistor cells 4 are not illustrated in detail in FIG. 1. Instead, in FIG. 1, each of the transistor cells 2 is represented by a controllable electronic switch with a parallel diode, which symbolize the functionality of the transistor cells. A detailed example of the transistor cells 4 is explained herein further below.

According to one example, forming the first and second superjunction regions 1, 2 includes forming a plurality of semiconductor layers one above the other, implanting first type dopant atoms and second type dopant atoms into each of the semiconductor layers, and an annealing process in order to diffuse and electrically activate the implanted dopant atoms. The semiconductor layers are epitaxially grown layers (epitaxial layers) according to one example, so that this type of process is sometimes referred to as multi-epi-multi-implant (MEMI) process.

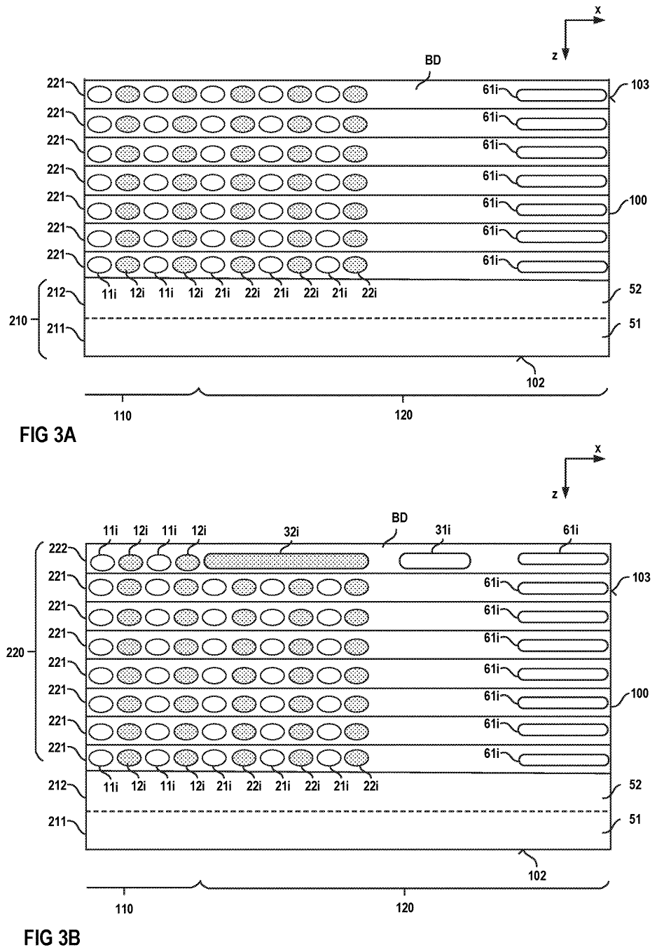

According to one example, the first and second termination regions 31, 32 are formed by the same process in which the first and second superjunction regions 1, 2 are formed. This makes it possible to produce the first and second termination regions 31, 32 in an efficient way and avoids the need for additional process sequences. A part of a method for forming the first and second termination region 31, 32 by the same process sequences as the first and second superjunction regions 1, 2 is illustrated in FIGS. 3A-3B. Each of FIGS. 3A-3B shows a vertical cross-sectional view of a portion of the semiconductor body 100 during the manufacturing process.

Referring to FIG. 3A, the method includes forming several first semiconductor layers 221 one above the other on top of a carrier 210, and implanting first type dopant atoms and second type dopant atoms into each of the first semiconductor layers 221 before the next first semiconductor layer 221 is formed (grown).

According to one example, the carrier 210 includes a semiconductor substrate 211 forming the drain region 51 in the finished device and an epitaxial layer 210 grown on top of the substrate 211 and forming the buffer region 52 in the finished device. The epitaxial layer forming the buffer region may be in-situ doped during the epitaxial growth process.

Referring to FIG. 3A, implanting the first type dopant atoms into each of the first semiconductor layers 221 forms first implanted regions 11i in the inner region 110 and third implanted regions 21i in the edge region 120. According to one example and as explained herein further below, the first implanted regions 11i and the third implanted regions 21i are formed by the same implantation process. The implantation process may include one implantation step at one implantation energy and a corresponding implantation dose. Alternatively, the implantation process may include two or more implantation steps at different implantation energies and different or the same implantation doses.

Implanting the second type dopant atoms into each of the first semiconductor layers 221 forms second implanted regions 12i in the inner region 110 and fourth implanted regions 22i in the edge region 120. According to one example and as explained herein further below, the second implanted regions 12i and the fourth implanted regions 22i are formed by the same implantation process. The implantation process may include one implantation step at one implantation energy and a corresponding implantation dose. Alternatively, the implantation process may include two or more implantation steps at different implantation energies and different or the same implantation doses.

Referring to FIG. 3A, in the first semiconductor layers 221, the first implanted regions 11i are formed one above the other in the vertical direction z, the second implanted regions 12i are formed one above the other in the vertical direction z, the third implanted regions 21i are formed one above the other in the vertical direction z, and the fourth implanted regions 22i are formed one above the other in the vertical direction z.

Referring to FIG. 3B, the method further includes forming a second semiconductor layer 222 on top of the first semiconductor layers 221. That is, the second semiconductor layer 222 is formed on top of a layer stack including the first semiconductor layers 221. The first semiconductor layer 221 and the second semiconductor layer 222 are epitaxial layers, for example.

Referring to FIG. 3B, the method further includes implanting first type dopant atoms in the inner region 110 of the second semiconductor layer 222 to form further first implanted regions 11i, and includes implanting second type dopant atoms in the inner region 110 of the second semiconductor layer 222 to form further second implanted regions 12i. The further first implanted regions 11i are formed above the first implanted regions 11i in the first semiconductor layers 221, and the further second implanted regions 12i are formed above the second implanted regions 12i in the first semiconductor layers 221.

Referring to FIG. 3B, the method further includes implanting first type dopant atoms and second type dopant atoms into the second semiconductor layer 222 in the edge region 120. The implanted first type dopant atoms form a first implanted termination region 31i, and the implanted second type dopant atoms form a second implanted termination region 32i. According to one example, the first implanted termination region 31i is formed by the same process in which the first implanted regions 11i are formed in the second semiconductor layer 222 in the inner region 110, and the second implanted region 32i is formed by the same process in which the second implanted regions 12i are formed in the second semiconductor layer 222 in the inner region 110.

According to one example, the first and second implanted regions 31i, 32i do not overlap. According to one example, the first and second implanted regions 31i, 32i are spaced apart from each other in lateral directions.

According to one example, the method further includes implanting first type dopant atoms into each of the first semiconductor layers 221 and the second semiconductor layer 222 in regions close to the edge surfaces 103 to form implanted field stop regions 61i. According to one example, the implanted field stop regions 61i are formed in the same process in which the first and third implanted regions 11i, 21i are formed in the first semiconductor layers 221 and the same process in which the first implanted regions 11i and the first implanted termination region 31i are formed in the second semiconductor layer 222.

It should be noted that the implantation processes explained above may take place at wafer level. That is, the implantation processes may take place when a plurality of semiconductor bodies are part of a wafer which is eventually diced to form the individual semiconductor bodies. At this stage of the manufacturing process, there are no edge surfaces of the semiconductor bodies. However, there are cutting lines on the wafer that define where the wafer will be diced, so that the position of the edge surfaces 103, the position of the inner region 110 and the position of the edge region 120 is already defined at wafer level. Thus, the terms inner region 110, edge region 120, and edge surface 103 are also used in the context of a semiconductor body which is still part of a wafer.

The method further includes a temperature process (annealing process) in which the implanted first and second type dopant atoms diffuse and are electrically activated in order to form the first and second superjunction regions 1, 2 and the first and second termination region 31, 32 illustrated in FIG. 1. More specifically, in the annealing process the first regions 11 of the first superjunction region 1 are formed based on the first implanted regions 11i; the second regions 12 of the first superjunction region 1 are formed based on the second implanted regions 12i; the third regions 21 of the second superjunction region 2 are formed based on the third implanted regions 21i; the fourth regions 22 of the second superjunction region 2 are formed based on the fourth implanted regions; the first termination region 31 is formed based on the first implanted termination region 31i; and the second termination region 32i is formed based on the second implanted termination region 32i. Furthermore, if implanted field stop regions 61i have been formed in the method according to FIGS. 3A-3B, the field stop region 61 is formed based on the implanted field stop regions 61i in the annealing process.

According to one example, implanting first and second type dopant atoms into the first and second semiconductor layers 221, 222 may include adjusting an implantation energy in the implantation processes such that the first and second type dopant atoms are implanted only into one of the first and second semiconductor layers 221, 222, namely that one of the semiconductor layers that was produced last before the respective implantation process. In the annealing process, dopant atoms implanted into one of the semiconductor layers 221, 222 may diffuse into adjoining semiconductor layers in the vertical direction z.

It should be noted that the semiconductor body 100 with the carrier 210 and the first and second semiconductor layers 221, 222 formed one above the other on top of the carrier 210 is a monocrystalline semiconductor body 100. That is, a border between the carrier 210 and the layer stack with the first and second semiconductor layers 221, 222 and between the individual semiconductor layers 221, 222 in the layer stack is not visible. In FIGS. 3A-3B, borders between the individual semiconductor layers are only shown for illustration purposes.

The first and second semiconductor layers 221, 222 may be produced to have a low basic doping concentration before the first and second type dopant atoms are implanted. According to one example, the basic doping concentration is lower than 1E14 cm⁻³ and may be as low as intrinsic. Regions of the first and second semiconductor layers 221, 222 that still have the basic doping concentration after the annealing process are referred to as basic doped regions BD.

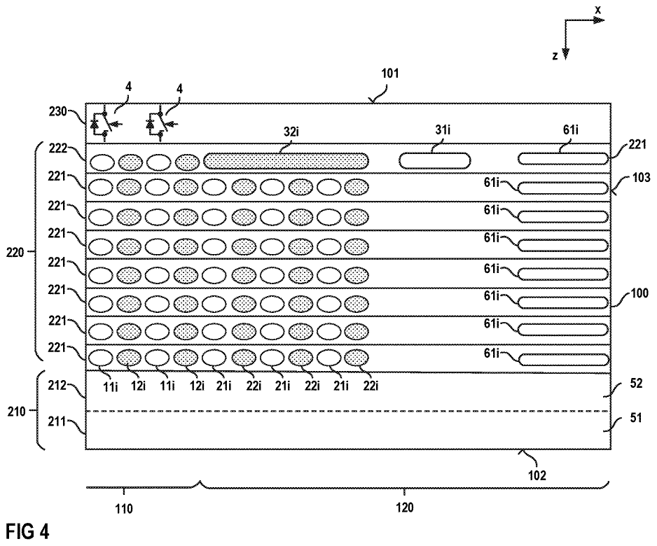

Referring to FIG. 4, the method further includes forming a third semiconductor layer 230 on top of the second semiconductor layer 222 and forming transistor cells 4 in the third semiconductor layer 230. The transistor cells 4 are only schematically illustrated in FIG. 4. Detailed examples of the transistor cells are explained herein further below.

Forming the transistor cells 4 may include implantation processes and an annealing process. The same annealing process may be used to form the first and second superjunction regions 1, 2 based on the first, second, third and fourth implanted regions 11i, 12i, 13i, 14i, the first and second termination regions 31, 32 based on the implanted first and second termination regions 31i, 32i, and the transistor cells 4 based on dopant atoms implanted into the third semiconductor layer 230.

In addition to dopant atoms for forming the transistor cells 4, first type dopant atoms may be implanted in the third semiconductor layer 230 in regions close to the edge surfaces to form further parts of the field stop region 61.

The first and second semiconductor layers 221, 222, into which the dopant atoms for forming the first and second superjunction regions 1, 2 and for forming the first and second termination regions 31, 32 are implanted, are buried in the semiconductor body 100 in the finished transistor device. The first and second semiconductor layer 221, 222 may also be referred to as base layers. The third semiconductor layer 230 formed on top of the layer stack 220 including the base layers may also be referred to as top semiconductor layer 230.

The overall number of the base layers with the first and second superjunction regions 1, 2 formed therein affects the voltage blocking capability of the transistor device. The voltage blocking capability is the maximum voltage between the drain and source nodes D, S the transistor device can withstand in an off-state (blocking state). According to one example, the overall number of base layers is between 15 and 25, in particular between 18 and 21. A thickness of the base layers, which is the dimension of the base layers in the vertical direction z, is between 1 5 micrometers and 2.5 micrometers, in particular between 1.8 micrometers and 2.1 micrometers, for example. According to one example, the base layers have substantially the same thickness.

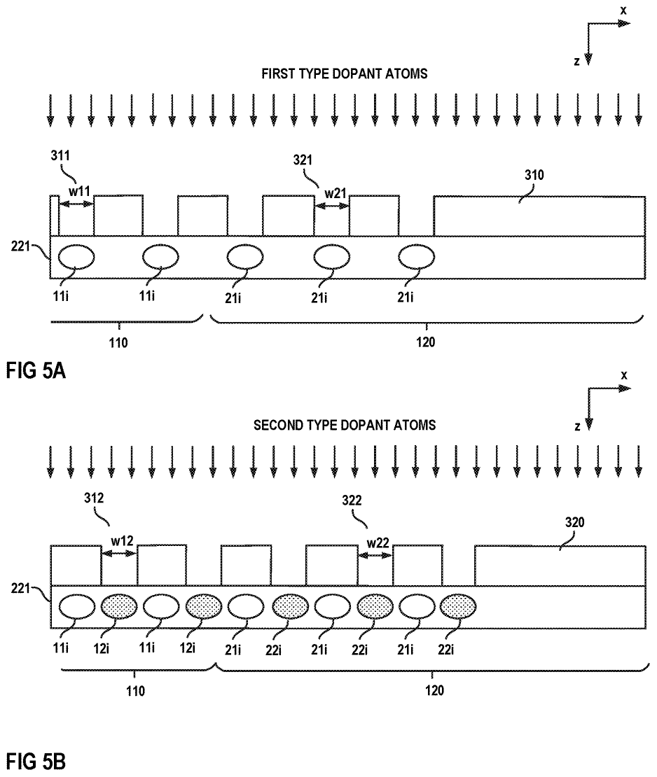

Referring to the above, forming the first and second superjunction regions 1, 2 includes implanting first and second type dopant atoms into each of several first semiconductor layers 221 formed one above the other. One example of a method for implanting first and second type dopant atoms into one of the first semiconductor layers 221 is illustrated in FIGS. 5A-5B, each of which illustrates a vertical cross-sectional view of one first semiconductor layer 221 during the implantation process.

FIG. 5A illustrates implanting first type dopant atoms into the first semiconductor layer 221. This includes implanting the first type dopant atoms through openings of a first implantation mask 310 into the first semiconductor layer 221. The first implantation mask 310 includes first openings 311 above the inner region 110 of the first semiconductor layer 221 and second openings 321 above the edge region 120 of the first semiconductor layer 221. The first type dopant atoms are implanted through the first and second openings 311, 321 into the first semiconductor layer 221, so that the first openings 311 define the position and size of the first implanted regions 11i and the second openings 321 define the position and size of the third implanted regions 21i in the first semiconductor layer 221.

Referring to the above, the first and third regions 11, 21 may be elongated in the second lateral direction y. In this example, the first and second openings 311, 321 in the first implantation mask 310 are elongated in the second lateral direction y.

The amount of dopant atoms included in each of the first and third implanted regions 11i, 21i is essential to the functionality of the superjunction transistor device. At a given implantation dose, the amount of dopant atoms included in each of the first implanted regions 11i can be adjusted by suitably selecting a width w12 of the first openings 311, and the amount of dopant atoms included in each of the third implanted regions 21i can be adjusted by suitably selecting a width w21 of the second openings 321. The widths w11, w21 are dimensions of the first and second openings 311, 321 in the first lateral direction x.

The implantation dose in the process of forming the first and third implanted regions 11i, 21i is selected from between 2E12 cm⁻² and 2E13 cm⁻², for example.

According to one example, the amount of dopant atoms included in the third implanted regions 21i decreases towards the edge surfaces 103. This can be achieved by reducing the width w21 of the second openings towards the edge surfaces 103 both in the first lateral direction x and the second lateral direction y.

According to one example, the first openings 311 in the first implantation mask 310 have the same width w11, so that each of the first implanted regions 11i substantially includes the same amount of dopant atoms.

FIG. 5B illustrates implanting second type dopant atoms into the first semiconductor layer 221. This includes implanting the second type dopant atoms through openings in a second implantation mask 320 provided after removing the first implantation mask 310. The second implantation mask 320 includes first openings 312 above the inner region 110 of the first semiconductor layer 221 and second openings 322 above the edge region 120 of the first semiconductor layer 221. The second type dopant atoms are implanted through the first and second openings 312, 322 into the first semiconductor layer 221, so that the first openings 312 define the position and size of the second implanted regions 12i and the second openings 322 define the position and size of the fourth implanted regions 22i in the first semiconductor layer 221.

Referring to the above, the second and fourth regions 12, 22 may be elongated in the second lateral direction y. In this example, the first and second openings 312, 322 in the second implantation mask 320 are elongated in the second lateral direction y.

The amount of dopant atoms included in each of the second and fourth implanted regions 12i, 22i is essential to the functionality of the superjunction transistor device. At a given implantation dose, the amount of dopant atoms included in each of the second implanted regions 12i can be adjusted both suitably selecting a width w12 of the first openings 312, and the amount of dopant atoms included in each of the fourth implanted regions 22i can be adjusted by suitably selecting a width w22 of the second openings 322. The widths w12, w22 are dimensions of the first and second openings 312, 322 in the first lateral direction x.

The implantation dose in the process of forming the second and fourth implanted regions 12i, 22i is selected from between 2E12 cm⁻² and 2E13 cm⁻², for example.

According to one example, the amount of dopant atoms included in the fourth implanted regions 22i decreases towards the edge surfaces 103. This can be achieved by reducing the width w22 of the second openings towards the edge surfaces 103 both in the first lateral direction x and the second lateral direction y.

According to one example, the first openings 312 in the second implantation mask 320 have the same width w12, so that each of the second implanted regions 12i substantially includes the same amount of dopant atoms.

According to one example, the implantation dose in the implantation process of implanting the first type dopant atoms according to FIG. 5A substantially equals the implantation dose in the implantation process of implanting the second type dopant atoms according to FIG. 5B. Furthermore, according to one example, the width w11 of the first openings 311 in the first implantation mask 310 substantially equals the width of first openings 312 in the second implantation mask 320, so that the amount of first type dopant atoms in the first implanted regions 11i substantially equals the amount of second type dopant atoms in the second implanted regions 12i. In this way, first and second regions 11, 12 can be formed that are balanced in view of the amount of dopant atoms included therein.

In the example illustrated in FIGS. 5A-5B, the first type dopant atoms are implanted into the first semiconductor layer 221 before the second type dopant atoms are implanted. This, however, is only an example. The order in which the first and second type dopant atoms are implanted is arbitrary.

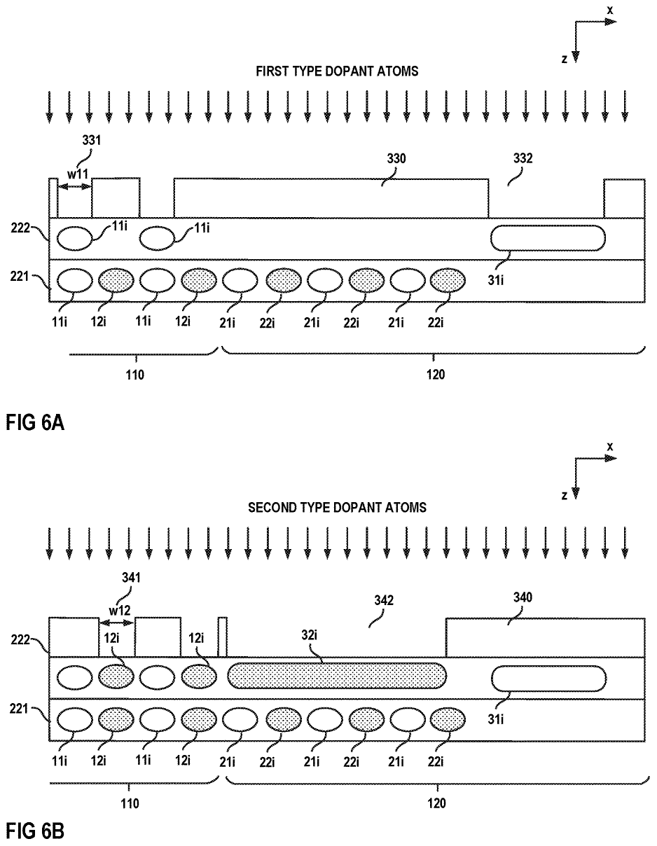

FIGS. 6A-6B illustrate one example of the method for forming the first and second implanted regions 11i, 12i and the first and second implanted termination regions 31i, 32i in the second semiconductor layer 222. Each of FIGS. 6A-6B shows a vertical cross-sectional view of the second semiconductor layer 222 and the first semiconductor layer 221 adjoining the second semiconductor layer 222 during the manufacturing process.

Referring to FIG. 6A, the method includes providing a first implantation mask 330 with first openings 331 and at least one second opening 332 above of the second semiconductor layer 222. Forming the first implanted regions 11i in the inner region 110 includes implanting first type dopant atoms through the first openings 331 in the first implantation mask 330 into the second semiconductor layer 222, and forming the first implanted termination region 31i in the edge region 120 includes implanting first type dopant atoms through the at least one second opening 332 in the first implantation mask 330. The dimensions of the first openings 331 may be the same as the dimensions of the first openings 311 in the first implantation mask 310 illustrated in FIG. 5A.

Referring to FIG. 6B, the method includes providing a second implantation mask 340 with first openings 341 and at least one second opening 342 on top of the second semiconductor layer 222. Forming the second implanted regions 12i in the inner region 110 includes implanting second type dopant atoms through the first openings 341 in the first implantation mask 330 into the second semiconductor layer 222, and forming the second implanted termination region 32i in the edge region 120 includes implanting second type dopant atoms through the at least one second opening 342 in the second implantation mask 340. The dimensions of the first openings 341 may be the same as the dimensions of the first openings 312 in the second implantation mask 320 illustrated in FIG. 5B.

In the implantation processes explained before, the implantation doses in the processes of implanting the first and second type dopant atoms into the first and second semiconductor layers 221, 222 are adapted to suitably generating the first and second regions 11, 12 of the first superjunction region 1. As explained above, by suitably adjusting the size of the second openings 321, 322 in the first and second implantation masks 310, 320 according to FIGS. 5A and 5B the amount of dopant atoms for forming the third and fourth regions 21, 22 of the second superjunction region 2 can be suitably adjusted.

Equivalently, by suitably adjusting the form and size of the second openings 332, 342 in the first and second implantation masks 330, 340 used for implanting first and second type dopant atoms into the second semiconductor layer 222 the amount of dopant atoms in the first and second termination regions 31, 32 can be suitably adjusted. Referring to the above, the first implantation mask 330 includes at least one second opening 332 for forming the first implanted termination region 31i, and the second implantation mask 340 includes at least one second openings 342 for forming the second implanted termination region 32i. According to one example, the first implantation mask 330 includes several second openings 332 and the second implantation mask 340 includes several second openings 342.

According to one example, the implantation dose in the process according to FIG. 6A for forming the first implanted regions 11i and the first implanted termination region 31i is selected from between 2E12 cm⁻² and 2E13 cm⁻², for example, and the implantation dose in the process according to FIG. 6B for forming the second implanted regions 12i and the second implanted termination region 32i is selected from between 2E12 cm⁻² and 2E13 cm⁻², for example.

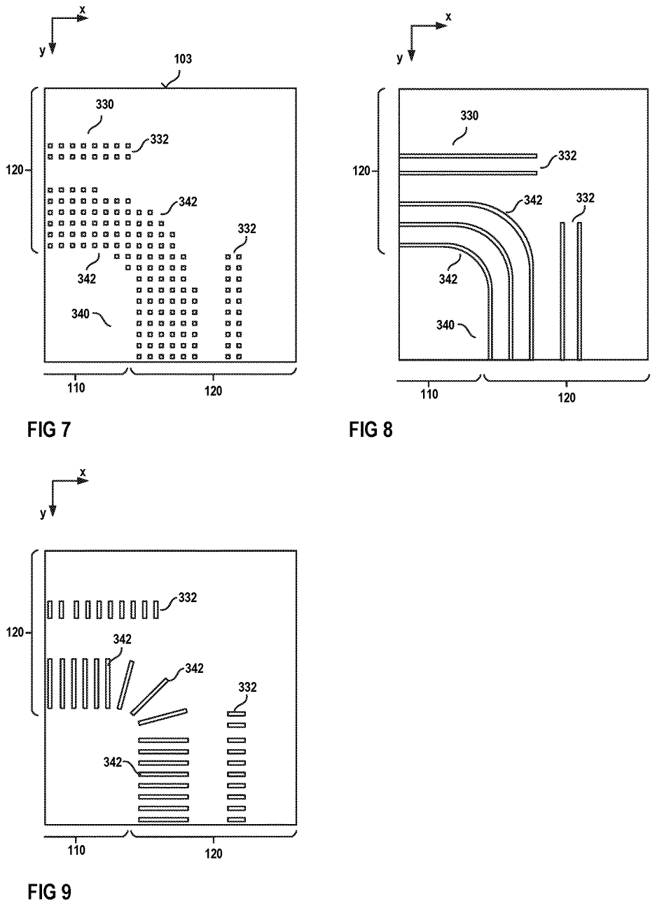

FIGS. 7-9 illustrate various examples of these second openings 332 in the first implantation mask 330 and these second openings 342 in the second implantation mask 340. Each of FIGS. 7-9 illustrates the position and form of the second openings 332 in the first implantation mask 330 above the semiconductor body 100 and the position and form of the second opening 342 in the second implantation mask 340 above the semiconductor body 100 in the same drawing. The position and size of the first openings 331, 341 used for forming the first and second implanted regions 11i, 12i in the inner region 110 are not illustrated.

In the example illustrated in FIG. 7, the first implantation mask 330 includes a plurality of point-like second openings 332. A cross-section of the point-like openings is rectangular, such as square, or elliptical, such as circular, for example. The second openings 332 form several lines of openings, wherein each line is essentially parallel to a respective one of the edge surfaces 103 and wherein each line includes a plurality of second openings 332 that are spaced apart from each other in the direction substantially parallel to the respective edge surface 103. The first implantation mask 330 includes at least one line of openings along each of the edge surfaces 103. In the example illustrated in FIG. 7, there are two lines of point-like openings along each edge surface 103. This, however, is only an example. It is also possible to implement the first implantation mask 330 with more than two lines of point-like openings in parallel with each edge surface 103.

Referring to FIG. 7, the second implantation mask 340 includes a plurality of point-like second openings 342. A cross-section of the point-like openings is rectangular or elliptical, for example. The second openings 342 are arranged such that the arrangement with the second openings 342 forms a ring surrounding the inner region 110 of the semiconductor body 100 below the second implantation mask 340. As illustrated in FIG. 7, the ring formed by the point-like second openings 342 may include several neighboring point-like openings in each lateral direction.

In the example illustrated in FIG. 8, the first implantation mask 330 includes elongated openings, wherein each of these elongated openings is substantially parallel with a respective one of the edge surfaces 103. The first implantation mask 330 includes at least one elongated opening 332 along each edge surface 103. In the example illustrated in FIG. 8, there are two elongated openings in parallel along each edge surface 103. This, however, is only an example. It is also possible to implement the first implantation mask 330 with more than two elongated openings in parallel with each edge surface 103.

Referring to FIG. 8, the second implantation mask 340 includes at least one ring-shaped second opening 342 surrounding the inner region 110 of the semiconductor body 100 arranged below. Just for the purpose of illustration, in the example illustrated in FIG. 8, there are three ring-shaped second openings 342 which are substantially concentric.

In the example illustrated in FIG. 9, the first implantation mask 330 includes a plurality of elongated second openings 332. These second openings 332 form four groups of openings, wherein the openings of each group are arranged next to each other in a direction perpendicular to their longitudinal direction and wherein each group forms a line substantially parallel with a respective one of the four edge surfaces 103.

Furthermore, in the example illustrated in FIG. 9, the second implantation mask 340 includes a plurality of elongated second openings 342, wherein these second openings longitudinally extend towards the edge surfaces 103 and together form a ring-like structure around the inner region 110 of the semiconductor body 100 arranged below.

It should be noted that each of the arrangements with the second openings 332 in the first implantation mask illustrated in FIGS. 7-9 can be combined with each of the arrangements with the second openings 342 in the second implantation mask illustrated in FIGS. 7-9. That is, for example, the arrangement with point-like second openings 332 in the first implantation mask 330 according to FIG. 7 can be combined with ring-shaped second openings 342 in the second implantation mask 340 according to FIG. 8, and so on.

In each of the examples illustrated in FIGS. 7-9, a width of the openings 332, 334 is selected from a range of between 0.2 micrometers and 2 micrometers, in particular between 0.5 micrometers and 1.5 micrometers. The width is the smallest lateral dimension of the respective openings 332, 334.

In each of the examples according to FIGS. 7-9 forming the at least one first implanted termination region 31i includes forming a plurality of first implanted termination regions 31i, wherein each second opening 332 in the first implantation mask 330 results in a first implanted termination region 31i. Furthermore, forming the at least one second implanted termination region 32i includes forming a plurality of second implanted termination regions 32i, wherein each second opening 342 in the second implantation mask 340 results in a second implanted termination region 32i. The form and position of the first implanted termination regions 31i corresponds to the form and position of the second openings 332 in the first implantation mask 330, and the form and position of the second implanted termination regions 32i corresponds to the form and position of the second openings 342 in the second implantation mask 340.

The first and second type dopant atoms implanted through the second openings 332, 342 in the first and second implantation mask 330, 340 into the second semiconductor layer 222 diffuse and are activated in the annealing process explained hereinabove. Dependent on the size and the mutual distance of the second openings 332 in the first implantation mask 330 a contiguous first termination region 31 or several neighboring first termination region 31 may be formed. Equivalently, dependent on the size and the mutual distance of the second openings 342 in the second implantation mask 340 a contiguous second termination region 32 or several second termination regions 32 may be formed. Just for the purpose of illustration, FIG. 1 shows one contiguous first termination region 31 and one contiguous second termination region 32. This, however, is only an example and only for illustration purposes.

Forming the first and second termination regions 31, 32 in the same process in which the first and second superjunction regions 1, 2 are formed, results in first and second termination regions 31, 32 which are arranged next to each other in lateral directions. More specifically, the first termination region 31 is arranged between the second termination region 32 and the edge surfaces 103, and the second termination region 32 is arranged between the first termination regions 31 and the inner region 110 with the transistor cells 4.

The operating principle of the superjunction transistor device according to FIG. 1 with the first and second superjunction regions 1, 2 and the first and second termination regions 31, 32 formed by the same process corresponds to the operating principle of a conventional superjunction transistor device. Further details of the superjunction transistor device according to FIG. 1 and the operating principle are explained in the following.

The transistor device can be operated in a forward biased mode (forward biased state) or a reverse biased mode (reverse biased estate). The reverse biased mode may also be referred to as diode mode of the transistor device. The transistor device is in the reverse biased mode when a polarity of a voltage applied between the drain node D and the source node S is such that the diodes in the transistor cells 4 are forward biased; and the transistor device is in the forward biased mode when the polarity of the voltage applied between the drain node D and the source node S is such that the diodes in the transistor cells 4 are reverse biased. In the forward biased mode, the transistor device can be operated in an on-state or an off-state. The transistor device is in the on-state when there are conducting channels in the transistor cells 4 between the source node S and the first regions 11 of the first superjunction region 1; and the transistor device is in the off-state when the conducting channels are interrupted.

According to one example, the transistor device is a gate-controlled transistor device. In this example, the presence of conducting channels in the transistor cells 4 is dependent on a voltage (gate-source voltage) applied between a gate node G and the source node S, so that the transistor device is in the on-state or the off-state dependent on the gate-source voltage.

The second regions 12 of the first superjunction region 1 are coupled to the source node S. This coupling of the second regions 12 to the source node S is only schematically illustrated in FIG. 1. According to one example, the second regions 12 are coupled to the source node S via the transistor cells 4. One example for coupling the second regions 12 to the source node S is explained herein further below. Furthermore, the first regions 11 of the first superjunction region 1 are coupled to the drain region 51 and the drain node D. The first regions 11 are coupled to the drain region 51 either directly by adjoining the drain region 51, or through the buffer region 52.

When the transistor device is in the off-state and a voltage is applied between the drain node D and the source node S space charge regions (depletion regions) expand in the first regions 11 and the second regions 12 beginning at the PN junctions formed between neighboring first and second regions 11, 12. This enables the first superjunction region 1, in a conventional way, to substantially absorb the voltage applied between the drain node D and the source node S in the inner region 110 of the transistor device.

Furthermore, when the transistor device is in the off-state and a voltage is applied between the drain node D and the source node S the edge termination structure, in particular the second superjunction region 2 and the first and second termination regions 31, 32, absorb the voltage applied between the drain node D and the source node S both in the vertical direction and in lateral directions. This is explained in the following.

Referring to FIG. 1, the second termination region 32 is coupled to the source node S. The coupling of the second termination region 32 to the source node S is only schematically illustrated in FIG. 1. One example for coupling the second termination region 32 to the source node S is explained in detail herein further below.

Referring to FIG. 1, the second termination region 32 is arranged between the second superjunction region 2 and the first surface 101. According to one example, the second termination region 32 extends at least as far towards the edge surface 103 as the second superjunction region 2, so that the second termination region 32 is arranged between each of the fourth regions 22 and the first surface 101. In other words, the second termination region 32, in the vertical direction z, is adjacent to each of the fourth regions 22. According to one example, this includes that the second termination region 32 adjoins each of the fourth regions 22. According to another example, the second termination region 32, in the vertical direction z, is spaced apart from the fourth regions 22.

If the second termination region 32 is spaced apart from the fourth regions 22 a region BD having the basic doping of the semiconductor body 100 may be arranged between the second termination region 32 and the fourth regions 22.

Regardless of whether the second termination region 32 adjoins the fourth regions 22 or the second termination region 32 is separated from the fourth regions 22 by a portion of the basic doped region BD, the fourth regions 22 are substantially electrically coupled to the second termination region 32, which is coupled to the source node S.

Inevitably, the electrical potential along the edge surface 103 of a vertical transistor device, such as a vertical transistor device of the type illustrated in FIG. 1, substantially equals the electrical potential of the drain region 51 (which is present in the inner region 110 and the edge region 120 of the transistor device). This is due to crystal defects along the edge surface is 103, for example. Referring to the above, the transistor device may include a field stop region 61 of the first doping type extending along the edge surfaces 103 from the drain region 51 or the optional buffer region 52 to first surface 101. The field stop region 61 ensures that the electrical potential along the edge surfaces 103 substantially equals the electrical potential of the drain region 51 and helps to widely avoid variations of the electrical potential along the edge surfaces 103.

In the off-state of the transistor device, the voltage difference between the field stop region 61 and the inner region 110 has its maximum close to the first surface 101. In the inner region 110 close to the first surface, the first superjunction region 1, in particular the second regions 12 coupled to the source node S, substantially has source potential. Thus, in the region of the first surface 101 the voltage difference between the field stop region 61 and the inner region 110 essentially equals the drain-source voltage. In the vertical direction z, the voltage difference between the field stop region 61 and the inner region 110 decreases towards the second surface 102 and reaches zero in the drain region 51 or the buffer region 52.

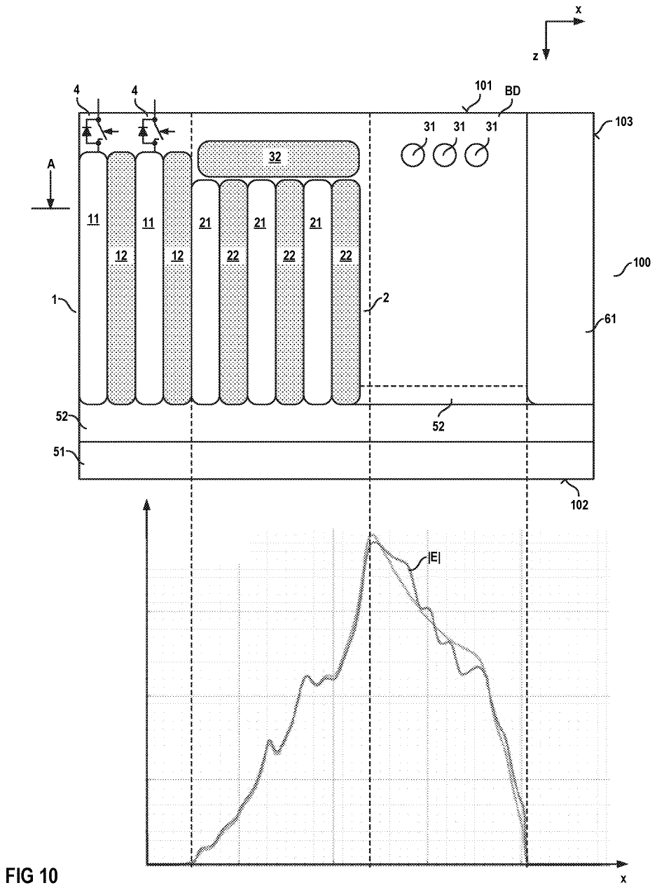

In the off-state of the transistor device, the first and second termination regions 31, 32 substantially absorb the drain source voltage in lateral directions. This is illustrated in FIG. 10, which shows the electric field along the first surface 101 between the field stop region 61 and the inner region 110 when the transistor device is in the off-state. More specifically, FIG. 10 illustrates the magnitude of the electric field along the first surface 101.

As can be seen from FIG. 10, the magnitude of the electric field increases in the region of the second termination region 32 towards the field stop region 61, reaches its maximum between the second and first termination regions 32, 31, decreases towards the field stop region 61 and reaches zero in the field stop region 61. The curve illustrated in FIG. 10 is based on simulation of a transistor device. Just for the purpose of illustration, the simulation is based on an example in which the first termination region 31 includes three sections that are spaced apart from each other in a direction perpendicular to the edge surface 103.

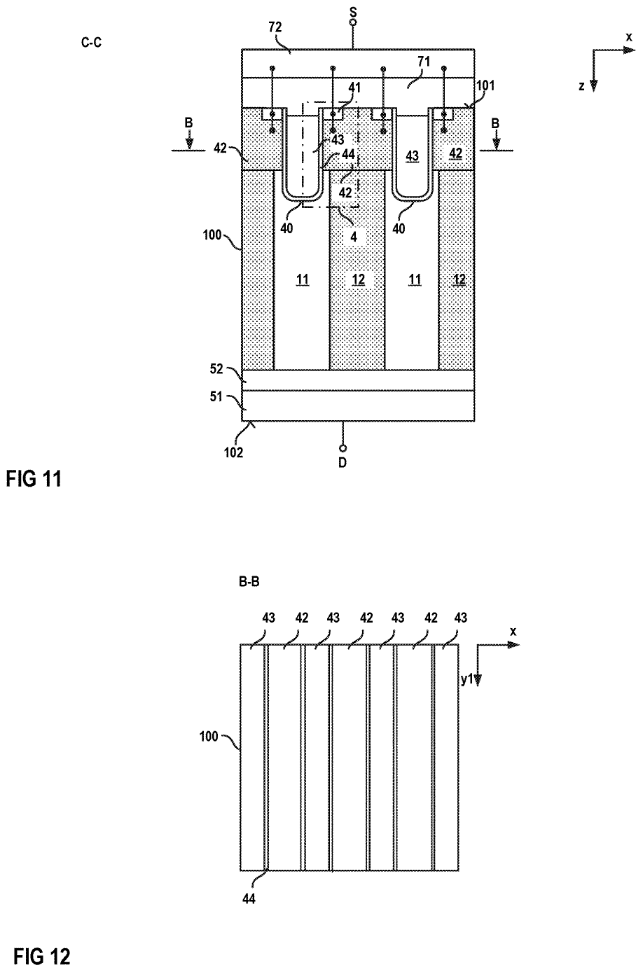

Referring to the above, the transistor device includes a plurality of transistor cells 4 each coupled between the source node S and at least one of the first regions 11 of the first superjunction region 1 and each configured to control the operating state of the transistor device when the transistor device is in the forward biased state. FIG. 11 illustrates transistor cells according to one example. More specifically, FIG. 11 illustrates a vertical cross-sectional view of one portion of the inner region 110 of the semiconductor body 100 in which the transistor cells 10 are implemented.

Referring to FIG. 11, each transistor cell 4 includes a source region 41 of the first doping type, a body region 42 of the second doping type (complementary to the first doping type), and a gate electrode 43. The gate electrode 43 is adjacent to the body region 42, is dielectrically insulated from the body region 42 by a gate dielectric 44 and is arranged in a gate trench 40 extending from the first surface 101 of the semiconductor body 100 into the semiconductor body 100.

Referring to FIG. 11, source and body regions 41, 42 of two neighboring transistor cells 4 may be arranged in a mesa region between neighboring gate trenches 40. In this example, the body regions 42 of the two neighboring transistor cells 4 may be formed by one contiguous doped region of the second doping type. Furthermore, two (other) neighboring transistor cells may share the gate electrode 43. That is, the gate electrodes 43 of two neighboring transistor cells may be formed by one contiguous electrode arranged in one gate trench 40.

The gate electrodes 43 include an electrically conductive material. Examples of the electrically conductive material include doped polysilicon, or a metal. The gate dielectric 44 includes an oxide, for example. According to one example, the oxide is silicon oxide (SiO₂).

Referring to the above, the source regions 41 of the transistor cells 4 are connected to the source node S of the transistor device. The transistor device may include a source electrode 72, which either forms the source node S or is connected to the source node S. The source electrode 72 includes an electrically conductive material such as, for example, aluminum (Al), copper (Cu), or an aluminum-copper alloy (AlCu).

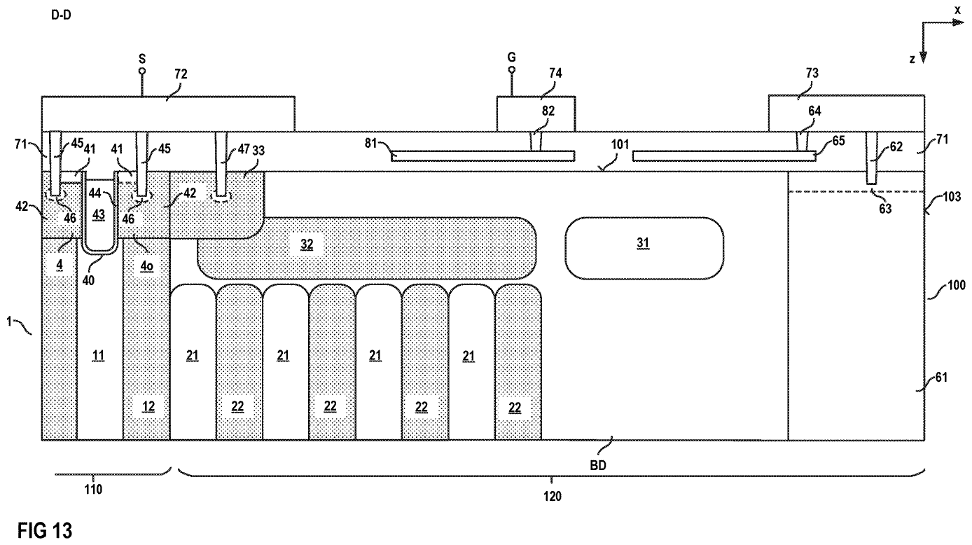

The source electrode 72 is electrically connected to the source and body regions 41, 42 of the transistor cells 40. Connections between the source electrode 72 and the source and body regions 41, 42 are only schematically illustrated in FIG. 11. Such connections may be implemented using electrically conductive vias that extend from the source electrode 72 through an insulating layer 71 to the source and body regions 41, 42. Examples of such vias are illustrated in FIG. 13 and explained below.

The gate electrodes 43 are connected to the gate node G. Connections between the gate electrodes 43 and the gate node G are not illustrated in FIG. 11. Examples of such connections are explained herein further below.

The insulating layer 71 is formed on top of the first surface 101 of the semiconductor body 100 and the gate electrodes 43 and separates the source electrode 72 from the semiconductor body 100 and the gate electrodes 43.

Referring to the above, the second regions 12 of the first superjunction region 1 are coupled to the source node S. In the example illustrated in FIG. 11, each of the second regions 12 adjoins the body region 42 of a respective transistor cell and is coupled to the source node S via the body region 42 of the transistor cell 4.

Forming the transistor cells 4 may include forming the gate electrodes 43 in the gate trenches 40, implanting first type dopant atoms to form the source regions 41, and implanting second type dopant atoms to form the body regions 42. The dopant atoms may be implanted before or after forming the gate electrodes 43. Forming the transistor cells 4 further includes an annealing process in which the implanted dopant atoms are activated. The annealing process can be the same annealing process used for activating the first and second superjunction regions 1, 2 and the first and second termination regions 31, 32.

Referring to the above, the transistor device can be operated in the on-state or the off-state. The transistor device is in the on-state when the gate-source voltage is such that a conducting channel is generated by the gate electrode 43 in the body region 42 along the gate dielectric. The transistor device is in the off-state when the conducting channel is interrupted. To enable a current flow from the source node S to the drain node D when the transistor device is in the on-state, that portion of the body region 42 in which the conducting channel is generated adjoins a respective first region 11. In this way, in the on-state, charge carriers can move from the source regions 41 along the conducting channels in the body regions 42, the first regions 11 of the first superjunction region 1 and the buffer region 52 to the drain region 51.

In the circuit symbols of the transistor cells 4 illustrated in FIG. 1, the electronic switch represents the conducting channel along the gate dielectric 44 in the body region 42. The diode in the circuit symbol represents a diode formed by a PN junction between the first region 11 (drift region) and the body region 42, which is usually referred to as body diode.

According to one example illustrated in FIG. 11, the gate trenches 40 with the gate electrodes are elongated. One example of elongated gate electrodes 43 is illustrated in FIG. 12.

FIG. 12 illustrates one portion of the semiconductor body 100 in a first horizontal section plane B-B shown in FIG. 11 that intersects the gate trenches 40 with the gate electrodes 43 and the gate dielectrics 44. The horizontal sectional plane B-B is essentially parallel to the first and second surfaces 101, 102.

According to one example, as illustrated in FIGS. 11 and 12, the gate trenches 40 with the gate electrodes 43 are spaced apart from each other in the first lateral direction x and longitudinally extend in the second lateral direction y. In this example, the gate trenches 40 extend longitudinally in the same direction in which the first and second regions 11, 12 extend longitudinally. According to another example (not illustrated) longitudinal directions of the gate trenches 40 with the gate electrodes 43 are perpendicular to longitudinal directions of the first and second regions 11, 12.

According to one example, the transistor device is an N-type transistor device. In this example, the regions of the first doping type, such as the drain and buffer regions 51, 52, the first and third regions 11, 13, the first termination region 31 and the source regions 41 are N-type regions and the regions of the second doping type, such as the second and fourth regions 12, 22 and the second termination region 32 are P-type regions. An N-type transistor device is in the forward biased mode when a positive voltage is applied between the drain node D and the source node S.

According to another example, the transistor device is a P-type transistor device. In this example, the regions of the first doping type are P-type regions and the regions of the second doping type are N-type regions.

Referring to the above, the second termination region 32 is coupled to the source node S. One example of connecting the second termination region 32 to the source node S is illustrated in FIG. 13.

FIG. 13 shows a vertical cross-sectional view of the edge region 120 and a portion of the inner region 110 of the transistor device. For connecting the source node S to the second termination region 32, the transistor device includes a connection region 33 of the second doping type which extends from the second termination region 32 to the body region 42 of an outermost transistor cell 4°. The outermost transistor cell 4o is a transistor cell located on a border between the inner region 110 and the edge region 120. FIG. 13 shows two transistor cells, the outermost transistor cell 4o and an adjacent transistor cell 4. According to one example, the outermost transistor cell 4o is implemented in the same way as the remainder of the transistor cells. According to another example, the outermost transistor cell 4o is devoid of a source region 41. Thus, the source region 41 of the outermost transistor cell 4o is illustrated in dashed lines in FIG. 13.

According to one example, a doping concentration of the connection region 33 is lower than a doping concentration of the body regions 42 and higher than the doping concentration of the second termination region 32.

The transistor cells 4, 4o shown in FIG. 13 are implemented in the same way as explained with reference to FIGS. 11 and 12. In addition to FIG. 11, FIG. 13 shows electrically conductive vias 45 that extend from the source electrode 72 through the insulating layer 71 to the source and body regions 41, 42 in order to connect the source and body regions 41, 42 to the source electrode 72. In order to provide an ohmic contact between the vias 45 and the body regions 42 contact regions 46 of the second doping type may be arranged between the vias 45 and the body regions 42. The contact regions 46 have a doping concentration that is high enough to achieve an ohmic contact between the vias 45 and the body regions 42. This doping concentration is higher than the doping concentration of the remainder of the body regions 42, for example.

Optionally, the transistor device includes a further electrically conductive via 47 that directly connects the connection region 33 to the source electrode 72.

In the transistor device according to FIG. 13, the edge termination structure further includes a drain field plate 65 arranged in the insulating layer 71 and connected to the field stop region 61 via a drain runner 73 arranged on top of the insulating layer 71 and electrically conductive vias 62, 64. The electrically conductive vias 62, 64 include a first via 62 connecting the field stop region 61 to the drain runner 73, and a second via 64 connecting the drain runner 73 to the drain field plate 65.

The field stop region 61 may include a contact region 63 of the first doping type and more highly doped than the remainder of the field stop region 61. In this example, the field stop region 61 is connected to the first via 62 by the contact region 63.

Referring to FIG. 13, the drain field plate 65, in lateral directions, may overlap the field stop region 61 on one side and the first termination region 31 on an opposite side. The drain field plate 65, which is connected to the field stop region 62 and therefore has drain potential, helps to shape the electric field in the edge region 120 along the first surface 101 of the semiconductor body 100. The drain field plate 65 includes highly doped polysilicon or a metal, for example. The drain runner 73 includes a metal, for example.

Referring to FIG. 13, the edge termination structure may further include a gate field plate 81 arranged in the insulating layer 71 and connected to a gate runner 74 formed above the insulating layer 71. The gate runner 74, in lateral directions, is arranged between the source electrode 71 and the drain runner 73 and is spaced apart from both the source electrode 72 and the drain runner 73. The gate runner 74 is connected to the gate field plate 81 by an electrically conductive via 82. According to one example, in lateral directions, the gate field plate 81 overlaps the first termination region 31 on one side and the second termination region 32 on an opposite side.

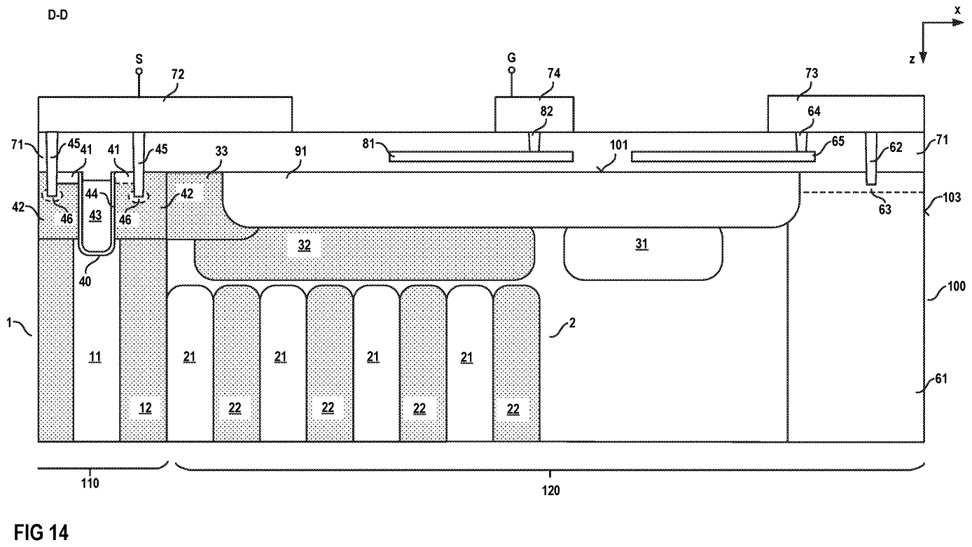

FIG. 14 shows a modification of the transistor device according to FIG. 13. In the example illustrated in FIG. 14, the edge termination structure further includes an insulating trench 91 in the first surface 101. The insulating trench 91 is a trench in the first surface 101 filled with an electrically insulating material, such as an oxide.

Referring to FIG. 14, the insulating trench 91, in lateral directions, may extend from the connection region 33 to the field stop region 61. The first and second termination regions 31, 32 may adjoin the insulating trench 91.

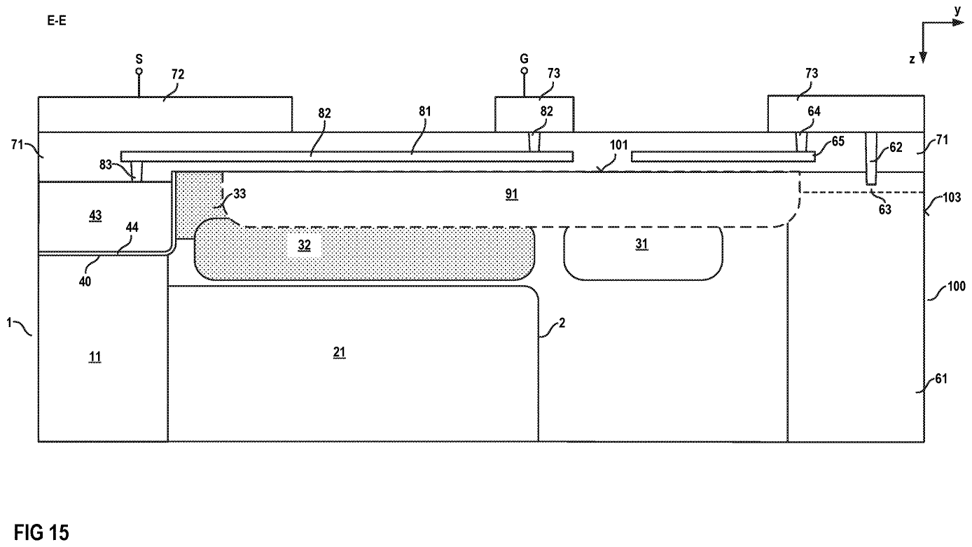

Referring to the above, the gate electrodes 43 are connected to the gate node G. According to one example, the gate electrodes 43 are elongated and connected to the gate node G in the region of at least one of two opposite longitudinal ends. FIGS. 13 and 14 show a vertical cross-sectional view of the transistor device in section planes that are perpendicular to the longitudinal directions of the gate electrodes 43. In the cross-sectional views illustrated in FIGS. 13 and 14 longitudinal ends of the gate electrodes 43 and thus connections between the gate electrodes 43 and the gate node G are out of view. One example of connecting the gate electrodes 43 to the gate node G is illustrated in FIG. 15.

FIG. 15 shows a vertical cross-sectional view of the transistor device in a section plane that intersects one gate electrode 43 in the longitudinal direction of the gate electrode 43. Referring to FIG. 15, a longitudinal end of the gate electrode 43 is connected to the gate runner 73 by a gate finger 82 arranged in the insulating layer 71. The gate finger 82 is connected to the gate electrode 43 by an electrically conductive via 83. Furthermore, the gate finger 82 may adjoin the gate field plate 81 connected to the gate runner 73. The gate runner 73 is connected to a gate pad (not illustrated in FIG. 15). The gate pad is connected to the gate node G or forms the gate node G of the transistor device.

Referring to the above, the insulating trench 91 is optional. Thus, the insulating trench 91 is illustrated in dashed lines in FIG. 15.

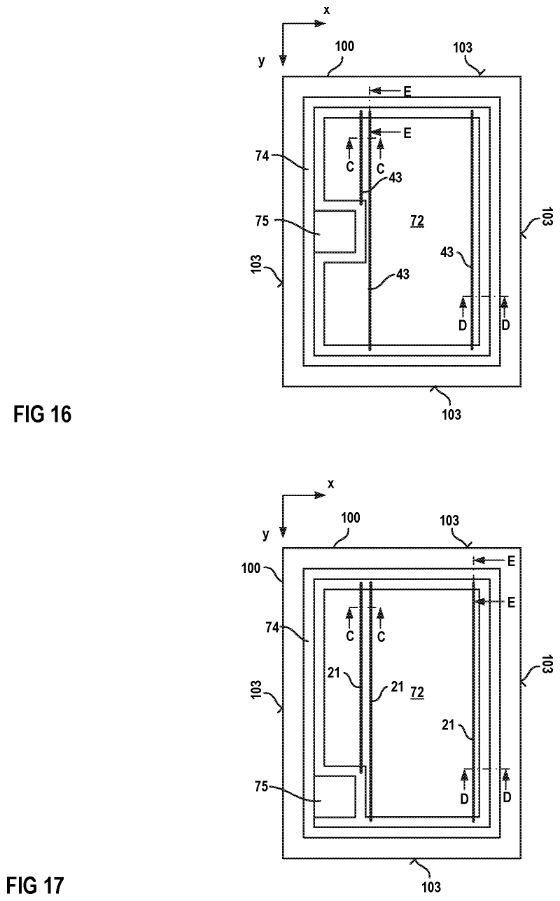

Each of FIGS. 16 and 17 illustrates a top view of a transistor device of the type explained herein before. More specifically, each of FIGS. 16 and 17 shows a top view of the semiconductor body 100 with the source electrode 72 and the gate runner 74 formed on top of the insulating layer 5. Referring to FIGS. 16 and 17, the gate runner 74 surrounds the source electrode 72 in lateral directions of the semiconductor body 100.

The transistor device furthermore includes a gate pad 75 that is connected to the gate runner 74. The gate pad 75 forms the gate node G or is connected to the gate node G of the transistor device. The gate pad 75 may adjoin the gate runner 74, as illustrated in FIGS. 16 and 17. Alternatively, the gate pad 75 is spaced apart from the gate runner 74 and a resistor (gate resistor) is connected between the gate pad 75 and the gate runner 74.

The drain runner surrounds the arrangement with the gate runner 74 and the gate pad 75, but, for the ease of illustration, is not illustrated in FIGS. 16 and 17.

In the example illustrated in FIG. 16, the gate pad 75 is arranged at a position that is essentially in the middle between two opposing sidewalls 103 of the semiconductor body 100. In the example according to FIG. 17, the gate pad 75 is arranged at a position that is close to a corner formed by two adjacent sidewalls 103 of the semiconductor body 100.

The transistor cells are out of view in FIGS. 16 and 17. For the purpose of illustration, the position of three gate electrodes 43 relative to the source electrode 72 and the gate runner 74 are illustrated by bold lines in FIGS. 16 and 17. In the example illustrated in FIGS. 16 and 17, the gate electrodes 43 are elongated electrodes, wherein a longitudinal direction of the gate electrodes 43 corresponds to the second lateral direction y explained herein before. The vertical cross-sectional view of the transistor cells illustrated in FIG. 11 is a cross-sectional view in section planes C-C illustrated in FIGS. 16 and 17, for example. The vertical cross-sectional view of the outermost transistor cell and an adjoining portion of the edge region illustrated in FIGS. 13 and 14 is a cross-sectional view in section planes D-D illustrated in FIGS. 16 and 17, for example. The vertical cross-sectional view illustrated in FIG. 15 is a cross-sectional view in section planes E-E illustrated in FIGS. 16 and 17, for example.

Some of the aspects explained above are briefly summarized in the following with reference to numbered examples.

### Example 1

A method for forming a superjunction device, wherein the method includes: forming a first superjunction region in an inner region of a semiconductor body, the first superjunction region including a plurality of first regions of a first doping type and a plurality of second regions of a second doping type complementary to the first doping type; forming a second superjunction region in an edge region of the semiconductor body, the second superjunction region including a plurality of third regions of the first doping type and a plurality of fourth regions of the second doping type; and forming a first termination region of the first doping type and a second termination region of the second doping type in the edge region, wherein forming the first superjunction region includes: forming a plurality of first semiconductor layers one above the other, forming a second semiconductor layer on top of the first semiconductor layers, and implanting first type dopant atoms and second type dopant atoms into each of the plurality of first semiconductor layers and the second semiconductor layer after forming the respective first or second semiconductor layer and before forming a next one of the first semiconductor layers or the second semiconductor layer before forming a next one of the first semiconductor layers or the second semiconductor layer, wherein forming the second superjunction region includes implanting first type dopant atoms and second type dopant atoms into each of the first semiconductor layers, wherein forming the first termination region includes implanting first type dopant atoms into the second semiconductor layer to form at least one first implanted termination region, and wherein forming the second termination region includes implanting second type dopant atoms into the second semiconductor layer to form at least one first implanted termination region.

### Example 2

The method according to example 1, wherein implanting the first type dopant atoms of the first superjunction region and the first type dopant atoms of the second superjunction region into a respective one of the first semiconductor layers includes implanting the first type dopant atoms in the same implantation process using the same implantation mask, and wherein implanting the second type dopant atoms of the first superjunction region and the second type dopant atoms of the second superjunction region into a respective one of the first semiconductor layers includes implanting the second type dopant atoms in the same implantation process using the same implantation mask.

### Example 3

The method according to example 1 or 2, wherein implanting the first type dopant atoms of the first superjunction region and the first type dopant atoms of the first implanted termination region into the second semiconductor layer includes implanting the second type dopant atoms in the same implantation process using the same implantation mask, and wherein implanting the second type dopant atoms of the first superjunction region and the second termination region into the second semiconductor layer includes implanting the second type dopant atoms in the same implantation process using the same implantation mask.

### Example 4

The method according to any one of examples 1 to 3, wherein the method further includes a temperature process to diffuse first type dopant atoms and second type dopant atoms implanted in the first semiconductor layers and the second semiconductor layer.

### Example 5

The method according to any one of examples 1 to 4, further including: forming a third semiconductor layer on top of the second semiconductor layer; and forming transistor cells at least partially in the third semiconductor layer in the inner region of the semiconductor body.

### Example 6

The method according to example 5, wherein forming the transistor cells includes a temperature process, and wherein the temperature process is the same temperature process used to diffuse the first and second type dopant atoms implanted in the first semiconductor layers and the second semiconductor layer.

### Example 7

The method according to any one of examples 1 to 6, wherein to form the at least one first implanted termination region includes forming a plurality of first implanted termination regions laterally spaced apart from each other.

### Example 8

The method according to any one of examples 1 to 7, wherein to form the at least one first implanted termination region includes forming a plurality of first implanted termination regions laterally spaced apart from each other.

### Example 9

The method according to any one of examples 1 to 8, wherein forming the second superjunction region includes forming the second superjunction region open to laterally surround the first superjunction region.

### Example 10

The method according to any one of examples 1 to 9, wherein the first and second regions of the first superjunction region are arranged alternately in a first lateral direction and are elongated in a second lateral direction.

### Example 11

The method according to example 10, wherein the third and fourth regions of the second superjunction region are arranged alternately in the first lateral direction and are elongated in the second lateral direction.

### Example 12

The method according to any one of examples 1 to 11, further including: forming a field stop region of the first doping type between the second superjunction region and edge surfaces of the semiconductor body.

### Example 13

The method according to example 12, wherein forming the field stop region includes implanting first type dopant atoms into each of the first semiconductor layers and the second semiconductor layer.

### Example 14

The method according to any one of examples 5 to 13, wherein forming the transistor cells includes forming an outermost transistor cell having a body region, and wherein the method further includes forming a connection region connecting the body region of the outermost transistor cell to the second termination region.

### Example 15

The method according to any one of examples 1 to 14, further including: forming an insulating trench in a first surface of the semiconductor body in the edge region, wherein the first and second termination regions are formed to adjoin the insulating trench.

### Example 16

The method according to any one of examples 1 to 15, wherein the semiconductor body includes monocrystalline silicon.

### Example 17

A superjunction device, including: a first superjunction region in an inner region of a semiconductor body, the first superjunction region including a plurality of first regions of a first doping type and a plurality of second regions of a second doping type complementary to the first doping type; a second superjunction region in an edge region of the semiconductor body, the second superjunction region including a plurality of third regions of the first doping type and a plurality of fourth regions of the second doping type; and a first termination region of the first doping type and a second termination region of the second doping type in the edge region, wherein the first termination region is arranged between the second termination region and edge surfaces of the semiconductor body in lateral directions.

### Example 18

The superjunction device of example 17, wherein the first termination region includes a plurality of first termination regions spaced apart from each other.

### Example 19

The superjunction device of example 17 or 18, wherein the second termination region includes a plurality of second termination regions spaced apart from each other.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for forming a superjunction device, the method comprising:
forming a first superjunction region in an inner region of a semiconductor body, the first superjunction region comprising a plurality of first regions of a first doping type and a plurality of second regions of a second doping type complementary to the first doping type;
forming a second superjunction region in an edge region of the semiconductor body, the second superjunction region comprising a plurality of third regions of the first doping type and a plurality of fourth regions of the second doping type; and
forming a first termination region of the first doping type and a second termination region of the second doping type in the edge region,
wherein forming the first superjunction region comprises:
forming a plurality of first semiconductor layers one above the other, forming a second semiconductor layer on top of the first semiconductor layers, and implanting first type dopant atoms and second type dopant atoms into each of the plurality of first semiconductor layers and the second semiconductor layer after forming the respective first or second semiconductor layer and before forming a next one of the first semiconductor layers or the second semiconductor layer before forming a next one of the first semiconductor layers or the second semiconductor layer,
wherein forming the second superjunction region comprises implanting first type dopant atoms and second type dopant atoms into each of the first semiconductor layers,
wherein forming the first termination region comprises implanting first type dopant atoms into the second semiconductor layer to form at least one first implanted termination region, and
wherein forming the second termination region comprises implanting second type dopant atoms into the second semiconductor layer to form at least one second implanted termination region.

2. The method of claim 1, wherein:
implanting the first type dopant atoms of the first superjunction region and the first type dopant atoms of the second superjunction region into a respective one of the first semiconductor layers comprises implanting the first type dopant atoms in a same implantation process using a same implantation mask; and
implanting the second type dopant atoms of the first superjunction region and the second type dopant atoms of the second superjunction region into a respective one of the first semiconductor layers comprises implanting the second type dopant atoms in a same implantation process using a same implantation mask.

3. The method of claim 1, wherein:
implanting the first type dopant atoms of the first superjunction region and the first type dopant atoms of the first implanted termination region into the second semiconductor layer comprises implanting the second type dopant atoms in a same implantation process using a same implantation mask; and
implanting the second type dopant atoms of the first superjunction region and the second termination region into the second semiconductor layer comprises implanting the second type dopant atoms in a same implantation process using a same implantation mask.

4. The method of claim 1, further comprising:
a temperature process to diffuse the first type dopant atoms and the second type dopant atoms implanted in the first semiconductor layers and the second semiconductor layer.

5. The method of claim 1, further comprising:
forming a third semiconductor layer on top of the second semiconductor layer; and
forming transistor cells at least partially in the third semiconductor layer in the inner region of the semiconductor body.

6. The method of claim 5, wherein:
forming the transistor cells includes a temperature process; and
the temperature process is a same temperature process used to diffuse the first and second type dopant atoms implanted in the first semiconductor layers and the second semiconductor layer.

7. The method of claim 5, wherein:
forming the transistor cells comprises forming an outermost transistor cell having a body region; and
the method further comprises forming a connection region connecting the body region of the outermost transistor cell to the second termination region.

8. The method of claim 1, wherein to form the at least one first implanted termination region comprises forming a plurality of first implanted termination regions laterally spaced apart from each other.

9. The method of claim 1, wherein to form the at least one second implanted termination region comprises forming a plurality of second implanted termination regions laterally spaced apart from each other.

10. The method of claim 1, wherein forming the second superjunction region comprises forming the second superjunction region open to laterally surround the first superjunction region.

11. The method of claim 1, wherein the first and second regions of the first superjunction region are arranged alternately in a first lateral direction and are elongated in a second lateral direction.

12. The method of claim 11, wherein the third and fourth regions of the second superjunction region are arranged alternately in the first lateral direction and are elongated in the second lateral direction.

13. The method of claim 1, further comprising:
forming a field stop region of the first doping type between the second superjunction region and edge surfaces of the semiconductor body.

14. The method of claim 13, wherein forming the field stop region comprises implanting first type dopant atoms into each of the first semiconductor layers and the second semiconductor layer.

15. The method of claim 1, further comprising:
forming an insulating trench in a first surface of the semiconductor body in the edge region,
wherein the first and second termination regions are formed to adjoin the insulating trench.

16. The method of claim 1, wherein the semiconductor body comprises monocrystalline silicon.

17. A superjunction device, comprising:
a first superjunction region in an inner region of a semiconductor body, the first superjunction region comprising a plurality of first regions of a first doping type and a plurality of second regions of a second doping type complementary to the first doping type;
a second superjunction region in an edge region of the semiconductor body, the second superjunction region comprising a plurality of third regions of the first doping type and a plurality of fourth regions of the second doping type; and
a first termination region of the first doping type and a second termination region of the second doping type in the edge region,
wherein the first termination region is arranged between the second termination region and edge surfaces of the semiconductor body in lateral directions.

18. The superjunction device of claim 17, wherein the first termination region includes a plurality of first termination regions spaced apart from each other.

19. The superjunction device of claim 17, wherein the second termination region includes a plurality of second termination regions spaced apart from each other.
